(19) United States
(12) Patent Application Publication
(10) Pub. No.: US 2016/0284517 A1
(43) Pub. Date: Sep. 29, 2016

(54) Substrate Processing Apparatus, Method of Manufacturing Semiconductor Device and Non-Transitory Computer-Readable Recording Medium

(71) Applicant: Hitachi Kokusai Electric Inc., Tokyo (JP)

(72) Inventor: Shuhei SAIDO, Toyama (JP)

(21) Appl. No.: 15/004,161

(22) Filed: Jan. 22, 2016

(30) Foreign Application Priority Data
Mar. 26, 2015 (JP) 2015-064840

(51) Int. Cl. H01J 37/32

(52) U.S. Cl. CPC H01J 37/3244; H01J 37/32357; H01J 2237/006; H01J 2237/3323

(57) ABSTRACT

A technology for forming a uniform film in a plane of a substrate involves a substrate processing apparatus including: a substrate support where a substrate is placed; a cover facing at least a portion of the substrate support, the cover including a gas supply channel at a center thereof; a gas supply structure connected to the gas supply channel; a reactive gas supply unit connected to the gas supply structure and including a plasma generating unit; a tube connected to the reactive gas supply unit and extending from the gas supply structure to the gas supply channel; and a gas supply unit connected to the gas supply structure and configured to supply a gas to a space between an outer surface of the tube and an inner surface of the gas supply structure.

### CROSS REFERENCE TO RELATED APPLICATIONS

This application claims foreign priority under 35 U.S.C. §119(a)-(d) to Application No. JP 2015-064840 filed on Mar. 26, 2015, the entire contents of which are hereby incorporated by reference.

### FIELD OF THE INVENTION

The present invention relates to a substrate processing apparatus, a method of manufacturing a semiconductor device and a non-transitory computer-readable recording medium.

### BACKGROUND

Recently, semiconductor devices such as flash memories and the like are becoming highly integrated. Thus, sizes of patterns are being significantly miniaturized. When patterns are formed, a process of performing a predetermined process such as oxidation or nitridation may be performed on a substrate as one of manufacturing processes. In such a process, a gas in a plasma state is used.

### SUMMARY

According to the miniaturization, it is further required to uniformly form patterns in a plane of the substrate, but plasma may not be uniformly supplied in the plane of the substrate. In this case, it is difficult to form a uniform film in the plane of the substrate.

The present invention provides a technique of forming a uniform film in a plane of a substrate in view of the above-described problem.

According to an aspect of the present invention, there is provided a technique including: a substrate support where a substrate is placed; a cover facing at least a portion of the substrate support, the cover including a gas supply channel at a center thereof; a gas supply structure connected to the gas supply channel; a reactive gas supply unit connected to the gas supply structure and including a plasma generating unit; a tube connected to the reactive gas supply unit and extending from the gas supply structure to the gas supply channel; and a gas supply unit connected to the gas supply structure and configured to supply a gas to a space between an outer surface of the tube and an inner surface of the gas supply structure.

### BRIEF DESCRIPTION OF THE DRAWINGS

FIG. 1 is a view illustrating a substrate processing apparatus according to a first embodiment of the present invention.

FIG. 2 is a cross-sectional view taken along line A-A′ of FIG. 1.

FIG. 3 is a flowchart illustrating a substrate processing process according to the present embodiment.

FIG. 4 is a flowchart illustrating a film forming process of FIG. 3 in detail.

FIG. 5 is a diagram illustrating operations of valves and the like in a film forming process.

FIG. 6A is a view illustrating a flow velocity of a gas which flows along a wall of a chamber lid assembly structure and a tube 261 in a gas distribution channel 231b.

FIG. 6B is a cross-sectional view taken along line a-a′ of FIG. 6A.

FIG. 6C is a cross-sectional view taken along line b-b′ of FIG. 6A.

FIG. 7 is a view illustrating an upper limit position of a lower end of a tube.

FIG. 8 is a view illustrating a lower limit position of the lower end of the tube.

FIG. 9 is a view for describing another example of a shape of a front end of the tube.

FIG. 10 is a view for describing still another example of the shape of the front end of the tube.

FIG. 11 is a view for describing a modification of the film forming process of FIG. 5.

FIG. 12 is a view for describing a comparative example of the shape of the front end of the tube.

### DETAILED DESCRIPTION

### First Embodiment

Hereinafter, a first embodiment of the present invention will be described.

### Configuration of Apparatus

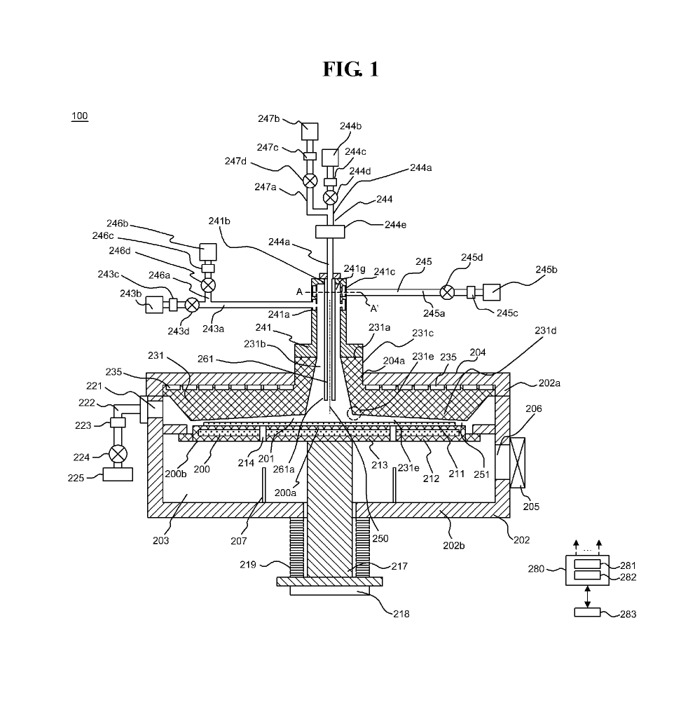

A configuration of a substrate processing apparatus 100 according to the present embodiment is illustrated in FIG. 1. The substrate processing apparatus 100 is configured as a single wafer substrate processing apparatus as illustrated in FIG. 1.

### (Process Container)

As illustrated in FIG. 1, the substrate processing apparatus 100 includes a process container 202. The process container 202 includes, for example, an airtight container with a circular and flat cross section. Also, the process container 202 is made of, for example, a metallic material such as aluminum (Al), stainless steel (SUS) or the like. A reaction zone (reaction chamber) 201 which processes a wafer 200 serving as a substrate such as a silicon wafer or the like and a transfer space 203 through which the wafer 200 passes when the wafer 200 is transferred to the reaction zone 201 are formed in the process container 202. The process container 202 includes an upper container 202a and a lower container 202b.

A substrate loading and unloading port 206 is installed adjacent to a gate valve 205 in a side surface of the lower container 202b. The wafer 200 moves to a transfer chamber (not illustrated) through the substrate loading and unloading port 206. A plurality of lift pins 207 are installed at a bottom of the lower container 202b.

A susceptor 212 serving as a substrate support where the wafer 200 is placed is installed in the reaction zone 201. The susceptor 212 mainly includes a substrate support surface 211 where the wafer 200 is placed and a heater 213 serving as a heating source embedded in the susceptor 212. Through holes 214 through which the lift pins 207 pass are installed in the susceptor 212 at positions corresponding to the lift pins 207.

The susceptor 212 is supported by a shaft 217. The shaft 217 passes through a bottom of the process container 202 and is connected to a lift mechanism 218 outside the process container 202. When the shaft 217 and the susceptor 212 are lifted by operating the lift mechanism 218, it is possible to lift the wafer 200 placed on the substrate support surface 211. Also, a vicinity of a lower end of the shaft 217 is covered with a bellows 219 and thus an inside of the process container 202 is air-tightly retained.

The susceptor 212 is lowered to a position (wafer transfer position) at which the substrate support surface 211 faces the substrate loading and unloading port 206 when the wafer 200 is transferred, and is lifted to a processing position (wafer processing position) at which the wafer 200 is positioned in the reaction zone 201, as illustrated in FIG. 1, when the wafer 200 is processed.

Specifically, when the susceptor 212 is lowered to the wafer transfer position, upper ends of the lift pins 207 protrude from an upper surface of the substrate support surface 211 and the lift pins 207 support the wafer 200 from below. Also, when the susceptor 212 is lifted to the wafer processing position, the lift pins 207 are buried under the upper surface of the substrate support surface 211 and the substrate support surface 211 supports the wafer 200 from below. Also, since the lift pins 207 are directly in contact with the wafer 200, the lift pins 207 are preferably formed of a material such as quartz, alumina or the like.

A cover assembly (cover unit) 231 is disposed above the reaction zone 201. A convex portion 231a of the cover assembly 231 is connected to a gas supply structure to be described below by passing through a hole 204a installed at the center of a top plate 204 constituting a portion of the upper container 202a. Also, when a low heat transfer conductive member is used, heat generated from the heater 213 is not easily transferred to the top plate 204 or a gas supply pipe to be described below.

At the center of the cover assembly (cover unit) 231, a gas distribution channel 231b serving as a gas supply channel is installed from the convex portion 231a toward a lower side of the cover assembly 231. The gas distribution channel 231b enables the gas supply structure to communicate with the reaction zone 201. The gas distribution channel 231b is tapered such that a diameter thereof increases when closer to the substrate support surface 211 and thus a gas is uniformly supplied to the wafer 200. That is, the cover assembly 231 is configured such that a diameter thereof gradually increases from a portion connected to an upper portion 241 serving as the gas supply structure to be described below toward a lower side thereof.

The gas distribution channel 231b extends in a direction perpendicular to a direction of the substrate support surface 211, passes through the cover assembly 231, and extends to a edge 231e. A portion of the gas distribution channel 231b is formed in a cylindrical shape along a central shaft 250 in the upper portion 241. Another portion of the gas distribution channel 231b is tapered to be spaced apart from the central shaft 250 at a side wall 231c of the gas distribution channel 231b. Also, the other portion of the gas distribution channel 231b is spaced further apart from the central shaft 250 than the side wall 231c in a lower portion 231d. The gas distribution channel 231b extends to the reaction zone 201 beyond the lower portion 231d and extends to a choke 251. The choke 251 adjusts flow of a gas between the reaction zone 201 and the process container 202.

As an embodiment, when the susceptor 212 is positioned at the processing position in the reaction zone 201, a minimum space between the edge 231e and the substrate support surface 211 on the susceptor 212 is within a range of 0.02 inches to 2.0 inches. Preferably, the minimum space is within a range of 0.02 inches to 0.2 inches. The space is changed according to a process condition in consideration of a supplied gas or heat conduction between the edge 231e and the susceptor 212.

In a surface in the cover assembly 231, which is in contact with the top plate 204, a thermal reduction unit 235 configured as a gap is installed along a surface of the top plate 204. The thermal reduction unit 235 attenuates thermal energy through the cover assembly 231 and the top plate 204 such that heat generated from the heater 213 is not transferred to a valve of the gas supply unit. For example, when the valve is exposed to a high temperature, the durability of the valve is significantly lowered. When the thermal reduction unit 235 is installed, a lifetime of the valve is prolonged.

### (Supply System)

The upper portion 241 is connected to the gas distribution channel 231b installed in the convex portion 231a. The upper portion 241 is formed in a tubular shape. A flange of the upper portion 241 and an upper surface of the convex portion 231a are fixed by screws (not illustrated) or the like. At least two gas supply pipes are connected to side walls of the upper portion 241.

A first gas supply pipe 243a, a second gas supply pipe 244a and a third gas supply pipe 245a are connected to the upper portion 241. The second gas supply pipe 244a is connected to the upper portion 241 through a remote plasma unit 244e serving as a plasma generating unit.

More specifically, the first gas supply pipe 243a is connected to a buffer chamber 241a. The second gas supply pipe 244a is connected to a hole 241b installed on a ceiling of the upper portion 241. The third gas supply pipe 245a is connected to a buffer chamber 241c.

As a gas supply pipe connected to a side surface of the upper portion 241, the third gas supply pipe 245a to which an inert gas is supplied is installed on an uppermost side. In such a configuration, a processing gas supplied through the first gas supply pipe 243a or the tube 261 is prevented from moving back into an upper space of the upper portion 241. When the processing gas is prevented from moving back, the formation of the film on an inner wall of the upper portion 241 constituting the upper space resulting from each gas is suppressed and thus the generation of particles is reduced.

A first-element-containing gas is mainly supplied through a first gas supply system 243 including the first gas supply pipe 243a and a second-element-containing gas is mainly supplied through a second gas supply system 244 including the second gas supply pipe 244a. When the wafer is processed through a third gas supply system 245 serving as an inert gas supply unit including the third gas supply pipe 245a, an inert gas is mainly supplied.

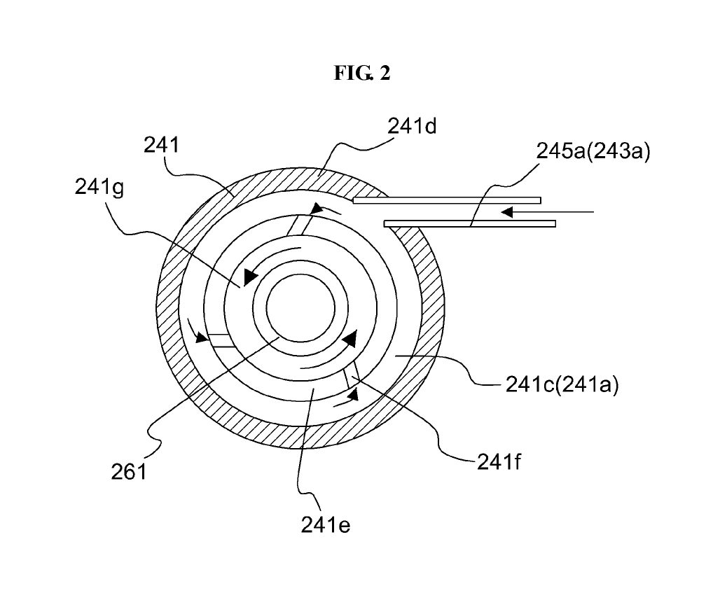

Next, relationships of the buffer chamber 241a and the buffer chamber 241c with the tube 261 will be described with reference to FIG. 2. Since the buffer chamber 241a and the buffer chamber 241c have the same configuration, the buffer chamber 241c is mainly described here and descriptions of the buffer chamber 241a are omitted. FIG. 2 is a cross-sectional view taken along line A-A′ of FIG. 1.

A reference numeral 241d represents an outer wall of the upper portion 241 and a reference numeral 241e represents an inner wall of the upper portion 241. The buffer chamber 241c is installed between the outer wall 241d and the inner wall 241e. A plurality of connecting holes 241f which communicate with a space 241g are installed in the inner wall 241e. The buffer chamber 241c communicates with the space 241g formed in an inner surface of the upper portion 241 through the plurality of connecting holes 241f. The connecting holes 241f are formed in a forward direction of gas flow such that the gas in the buffer space 241c is smoothly supplied to the space 241g.

Also, a groove having a spiral shape may be installed at a wall of the inner wall 241e facing the space 241g in the inner surface or a wall of the tube 261 in a forward direction of the gas flow. When the groove is installed, it is possible to repeatedly form a spiral-shaped flow. In such a configuration, since the supplied gas is supplied to edges of the wafer 200, it is possible to form a more uniform film.

Next, the flow of the gas will be described. The gas supplied through the supply pipe 245a is supplied to the buffer space 241c. In this case, the supply pipe 245a supplies the gas in a direction of a tangent line to the inner wall 241e. The gas supplied to the buffer space 241c flows in a direction of an arrow and is supplied to the space 241g in the inner surface through the connecting holes 241f. When such a structure is provided, it is possible to form a swirl in the space 241g which is an outside of the tube 261 in an arrow direction. The swirl is referred to as an eddy generating unit formed by the buffer space 241c, the inner wall 241e and the connecting holes 241f.

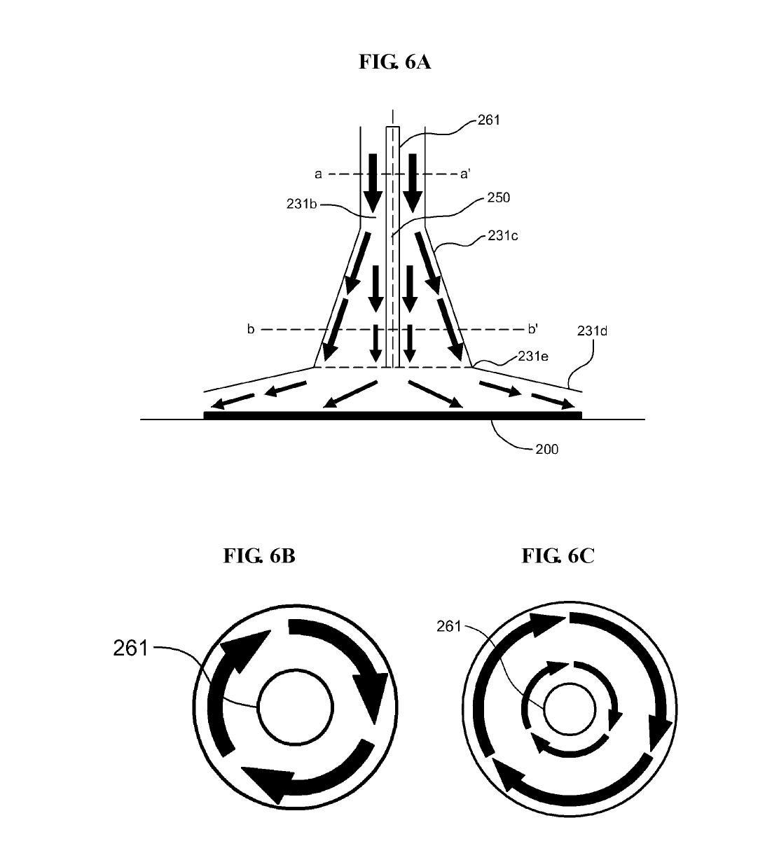

FIGS. 6A through 6C are views illustrating a simulation result showing the flow of the gas in the case in which the structure of FIG. 2 is used. FIG. 6A is a view illustrating a flow velocity of the gas which flows along a wall of a cover assembly structure and the tube 261 in the gas distribution channel 231b. FIG. 6B is a cross-sectional view taken along line a-a′ of FIG. 6A, and specifically, a cross-sectional view illustrating the gas distribution channel in the upper portion 241. FIG. 6C is a cross-sectional view taken along line b-b′ of FIG. 6A.

Higher flow velocities are represented by thicker arrows. Therefore, it may be seen that the flow velocity of the gas decreases when closer to the central shaft 250 [when closer to the tube 261]. That is, the flow velocity of the gas which flows along the side wall 231c is greater than the flow velocity of the gas which flows along the tube 261. Also, it may be seen that the flow velocity of the gas decreases when closer to the substrate 200. That is, the flow velocity of the gas decreases when a diameter of the gas distribution channel 231b increases. It may be seen that the flow of the gas in the gas distribution channel 231b is formed when the gas is supplied in the same manner as in the structure illustrated in FIG. 2. Since the diameter of the gas distribution channel 231b increases below the edge 231e, the flow of the gas is further diffused below the edge 231e. Therefore, it is possible to uniformly transfer the gas supplied through the first gas supply pipe 243a and the third gas supply pipe 245a into a plane of the wafer. Here, the edge 231e refers to an edge which is formed between the side wall 231c and the lower portion 231d, in which the diameter of the gas distribution channel 231b is changed.

Also, for example, in the case in which a gas in a plasma state is supplied through the first gas supply pipe 243a or the third gas supply pipe 245a illustrated in FIG. 2, the plasma is considered to be deactivated before reaching the wafer 200.

For example, when the plasma is supplied to the structure of FIG. 2, since the gas collides with walls constituting the connecting hole 241f or the buffer space 241c, the plasma is considered to be deactivated before being supplied to the space 241g in the inner surface.

Returning to FIG. 6, since the gas supplied to the space 241g in the inner surface flows in a spiral shape as shown by the flow of the arrows, decomposed components of the gas are considered to collide with the wall or the like when the flow velocity of the gas increases. Thus, the plasma supplied to the space 241g in the inner surface is deactivated before being supplied to the wafer 200.

Therefore, in the present embodiment, the tube 261 to be described below is installed at substantially a center portion of the gas distribution channel 231b. The plasma flows in the tube 261 and the plasma is transferred to a place at which the flow velocity of the gas decreases. In such a configuration, the deactivation of the plasma is suppressed and thus the plasma may be transferred to the wafer 200.

### (Tube)

The gas supply pipe 244a is connected to the tube 261 through the hole 241b of the upper portion 241. A lower end 261a of the tube 261 extends toward the reaction zone 201. The tube 261 is made of, for example, quartz.

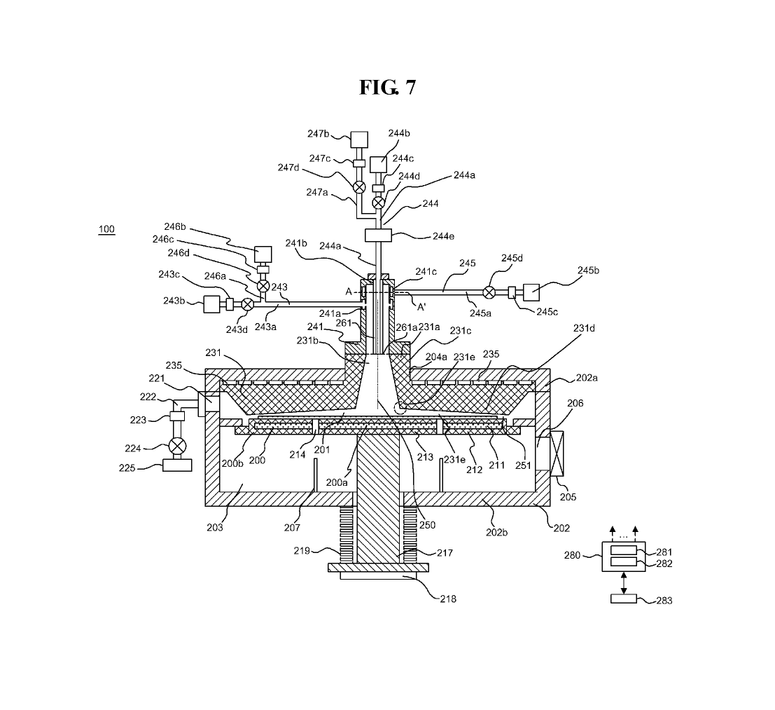

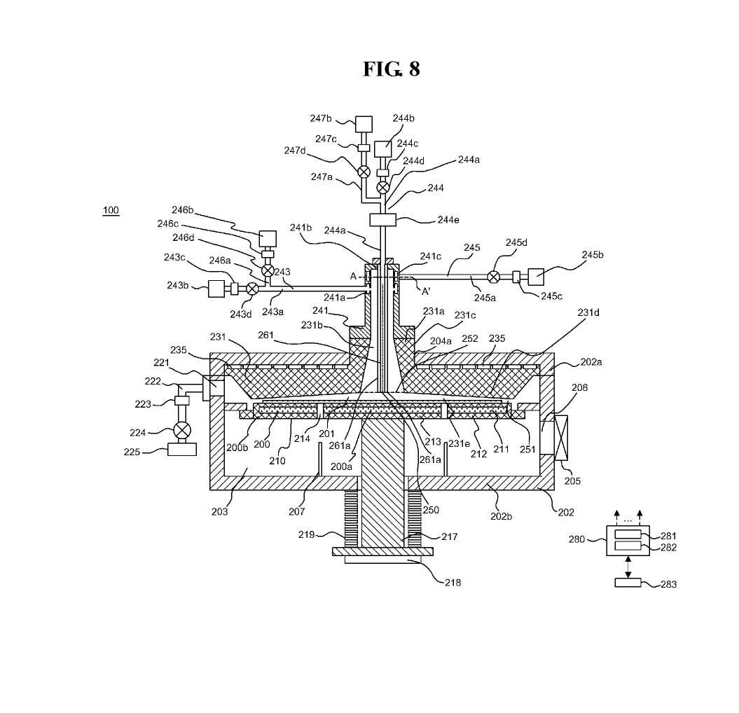

The lower end 261a of the tube 261 is set between a region (see FIG. 7) in which a diameter of the gas distribution channel 231b increases and a region (see FIG. 8) in which a direction of the gas flow is changed into the channel 231b. That is, a lower limit of the lower end 261a is set to an extension line 252 in a direction of the central shaft 250 of the lower portion 231d.

Here, “the region in which the diameter of the gas distribution channel 231b increases” refers to a region in which the diameter thereof is greater than a diameter of the space 241g in the inner surface, and refers to, for example, a region including a portion to which the upper portion 241 and the convex portion 231a are connected. Also, “the region in which the direction of the gas flow is changed into the channel 231b” refers to a region in which the diameter of the gas distribution channel 231b increases, and refers to, for example, a region in the vicinity of the edge 231e. Therefore, quantitatively, the lower end 261a of the tube 261 is set such that the front end 261a is maintained between an upper end of the convex portion 231a and the edge 231e in a height direction. When the lower end 261a of the tube 261 is set to the position in this manner, the deactivation of the plasma is suppressed and it is possible to transfer the plasma to the outer circumference of the wafer by placing the plasma on the above-described flow of the inert gas having a spiral shape.

### (First Gas Supply System)

In the first gas supply pipe 243a, a first gas supply source 243b, a mass flow controller (MFC) 243c serving as a flow rate controller (flow rate control unit) and a valve 243d serving as an opening and closing valve are sequentially installed from an upstream end.

A gas containing a first element (hereinafter referred to as “a first-element-containing gas”) is supplied to the reaction zone 201 through the first gas supply pipe 243a via the MFC 243c, the valve 243d and the upper portion 241.

The first-element-containing gas is a source gas, that is, one of processing gases. Here, the first element is, for example, titanium (Ti). That is, the first-element-containing gas is, for example, a titanium-containing gas. Also, the first-element-containing gas may be any one of a solid, a liquid and a gas at a room temperature and normal pressure. When the first-element-containing gas is liquid at the room temperature and normal pressure, a vaporizer (not illustrated) may be installed between the first gas supply source 243b and the MFC 243c. Here, the first-element-containing gas serving as a gas will be described.

A downstream end of a first inert gas supply pipe 246a is connected downstream from the valve 243d of the first gas supply pipe 243a. In the first inert gas supply pipe 246a, an inert gas supply source 246b, an MFC 246c serving as a flow rate controller (flow rate control unit) and a valve 246d serving as an opening and closing valve are sequentially installed from an upstream end.

Here, the inert gas is, for example, nitrogen (N₂) gas. Also, as the inert gas, in addition to the N₂ gas, rare gases such as helium (He) gas, neon (Ne) gas, argon (Ar) gas and the like may be used.

A first-element-containing gas supply system 243 (also referred to as a titanium-containing gas supply system or a source gas supply unit) mainly includes the first gas supply pipe 243a, the MFC 243c and the valve 243d.

Also, a first inert gas supply system mainly includes the first inert gas supply pipe 246a, the MFC 246c and the valve 246d. Also, the inert gas supply source 246b and the first gas supply pipe 243a may be considered as being included in the first inert gas supply system.

Also, the first gas supply source 243b and the first inert gas supply system may be considered as being included in the first-element-containing gas supply system 243.

### (Second Gas Supply System)

The remote plasma unit 244e is installed downstream from the second gas supply pipe 244a. In the second gas supply pipe 244a, a second gas supply source 244b, an MFC 244c serving as a flow rate controller (flow rate control unit) and a valve 244d serving as an opening and closing valve are sequentially installed from an upstream end.

A gas containing a second element (hereinafter referred to as “a second-element-containing gas”) is supplied to the reaction zone 201 through the second gas supply pipe 244a via the MFC 244c, the valve 244d, the remote plasma unit 244e, the upper portion 241 and the tube 261. A second gas is changed into a plasma state after passing through the remote plasma unit 244e and supplied to the wafer 200.

The second-element-containing gas is one of the processing gases. Also, the second-element-containing gas may be considered as an inert gas or a modifying gas.

Here, the second-element-containing gas contains a second element different from the first element. The second element is, for example, any one of oxygen (O), nitrogen (N) and carbon (C). In the present embodiment, the second-element-containing gas is, for example, a nitrogen-containing gas. Specifically, as the nitrogen-containing gas, ammonia (NH₃) gas is used.

A second-element-containing gas supply system 244 (also referred to as a nitrogen-containing gas supply system or an inert gas supply unit) mainly includes the second gas supply pipe 244a, the MFC 244c and the valve 244d.

Also, a downstream end of a second inert gas supply pipe 247a is connected downstream from the valve 244d of the second gas supply pipe 244a. In the second inert gas supply pipe 247a, an inert gas supply source 247b, an MFC 247c serving as a flow rate controller (flow rate control unit) and a valve 247d serving as an opening and closing valve are sequentially installed from an upstream end.

An inert gas is supplied to the reaction zone 201 through the second inert gas supply pipe 247a via the MFC 247c, the valve 247d, the second gas supply pipe 244a, the remote plasma unit 244e and the tube 261. The inert gas serves as a carrier gas or a dilution gas in a thin film forming process (S104).

A second inert gas supply system mainly includes the second inert gas supply pipe 247a, the MFC 247c and the valve 247d. Also, the inert gas supply source 247b, the second gas supply pipe 244a and the remote plasma unit 244e may be considered as being included in the second inert gas supply system.

Also, the second gas supply source 244b, the remote plasma unit 244e and the second inert gas supply system may be considered as being included in the second-element-containing gas supply system 244.

### (Third Gas Supply System)

In the third gas supply pipe 245a, a third gas supply source 245b, an MFC 245c serving as a flow rate controller (flow rate control unit) and a valve 245d serving as an opening and closing valve are sequentially installed from an upstream end.

An inert gas serving as a purge gas flows in a spiral shape and is supplied to the reaction zone 201 through the third gas supply pipe 245a via the MFC 245c, the valve 245d and the buffer chamber 241c.

Here, the inert gas is, for example, nitrogen (N₂) gas. Also, as the inert gas, in addition to the N₂ gas, rare gases such as helium (He) gas, neon (Ne) gas, argon (Ar) gas and the like may be used.

A third gas supply system 245 (also referred to as a gas supply unit or an inert gas supply unit) mainly includes the third gas supply pipe 245a, the MFC 245c and the valve 245d.

In the substrate processing process, the inert gas is supplied to the reaction zone 201 through the third gas supply pipe 245a via the MFC 245c and the valve 245d.

In the substrate processing process, the inert gas supplied from the third gas supply source 245b serves as a purge gas which purges the process container 202, the gas distribution channel 231b and an upper space of the upper portion 241. Also, the inert gas serves as a gas which transfers the second-element-containing gas in a plasma state, which is supplied through the tube 261, to an outer circumference 200b of the wafer.

### (Exhaust System)

An exhaust system that exhausts an atmosphere in the process container 202 includes an exhaust pipe 222 connected to an exhaust hole 221 installed on a side wall of the reaction zone 201. In the exhaust pipe 222, an auto pressure controller (APC) 223 which is a pressure controller for controlling a pressure in the reaction zone 201 to a predetermined pressure is installed. The APC 223 includes a valve main body (not illustrated) for adjusting a degree of opening and adjusts the conductance of the exhaust pipe 222 according to an instruction from a controller 280 to be described below. In the exhaust pipe 222, a valve 224 is installed downstream from the APC 223. A pump 225 is connected downstream from the valve 224. The exhaust pipe 222, the APC 223 and the valve 224 are collectively referred to simply as an exhaust system. Also, the exhaust system may also be considered to include the pump 225.

### (Controller)

The substrate processing apparatus 100 includes the controller 280 that controls operations of respective units of the substrate processing apparatus 100. The controller 280 includes at least a calculating unit 281 and a storage unit 282. The controller 280 is connected to the above-described each configuration, calls a program or a recipe from the storage unit 282 according to an instruction of a top controller or a user and controls an operation of each configuration in response to content thereof.

Also, the controller 280 may be configured as a dedicated computer and as a general-purpose computer. For example, the controller 280 according to the present embodiment may be configured by preparing an external memory device 283 (e.g., a magnetic tape, a magnetic disk such as a flexible disk or a hard disk, an optical disc such as a compact disc (CD) or a digital video disc (DVD), a magneto-optical disc such as a magneto-optical (MO) drive or a semiconductor memory such as a Universal Serial Bus (USB) memory (USB Flash Drive) or a memory card) recording the above-described program and installing the program in the general-purpose computer using the external memory device 283. Also, a method of supplying the program to the computer is not limited to using the external memory device 283. For example, a communication line such as the Internet or a dedicated line may be used to supply the program without using the external memory device 283.

Also, the storage unit 282 or the external memory device 283 is configured as a non-transitory computer-readable recording medium. Hereinafter, these are also collectively referred to simply as a recording medium. Also, when the term “recording medium” is used in this specification, it refers to either or both of the storage unit 282 and the external memory device 283.

### Substrate Processing Process

Next, a process of forming a thin film on the wafer 200 using the substrate processing apparatus 100 will be described. Also, in the following description, operations of respective units are controlled by the controller 280.

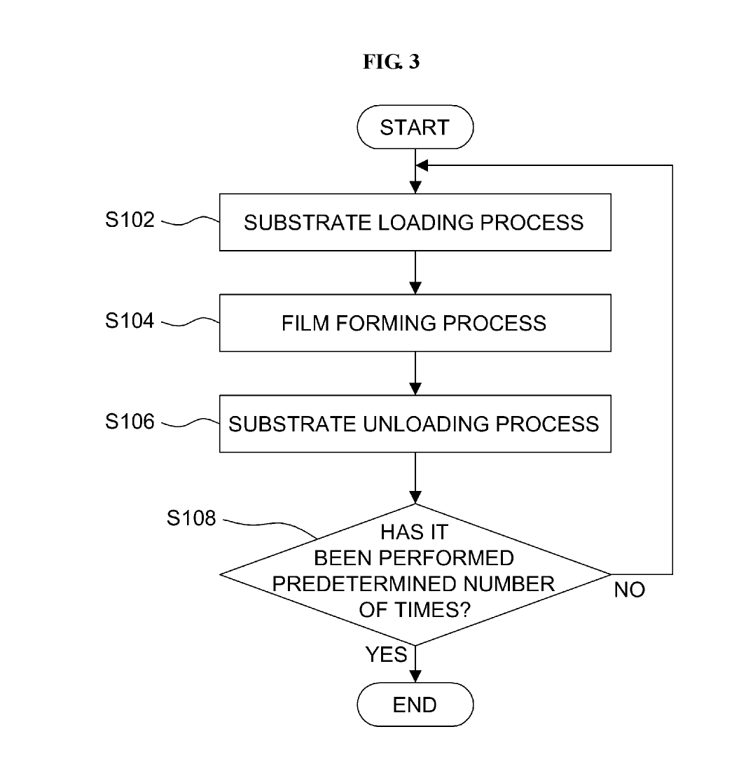

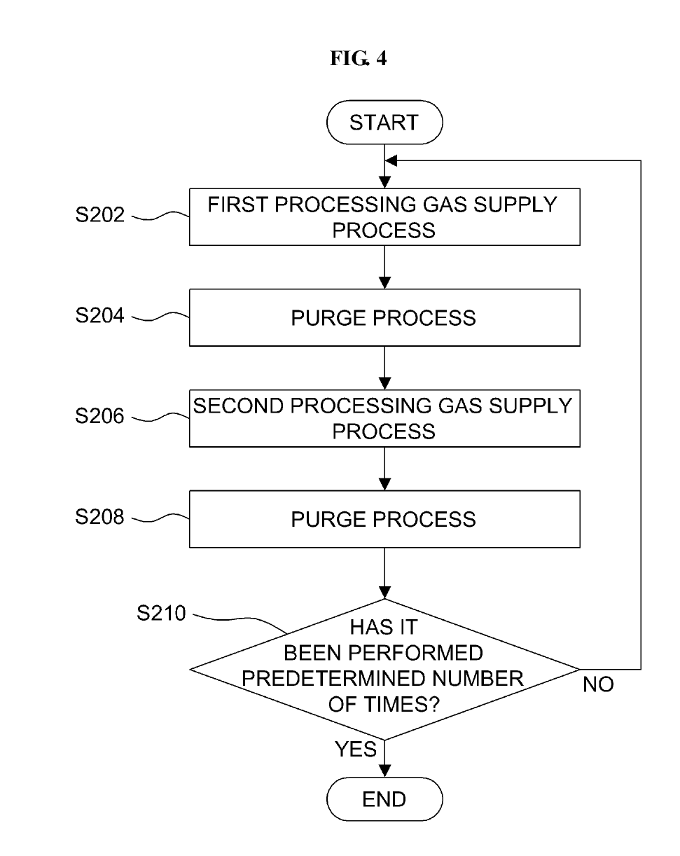

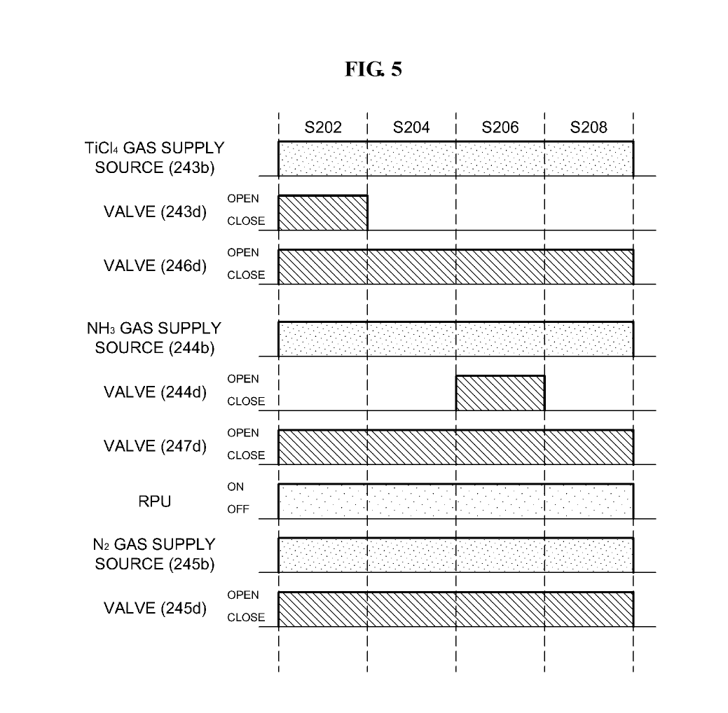

FIG. 3 is a flowchart illustrating a substrate processing process according to the present embodiment. FIG. 4 is a flowchart illustrating a film forming process of FIG. 3 in detail. FIG. 5 is a diagram illustrating operations of valves in the film forming process.

Hereinafter, an example of forming a titanium nitride film serving as a thin film on the wafer 200 using a Ti-containing gas (e.g., TiCl₄) serving as the first-element-containing gas and a nitrogen-containing gas (e.g., NH₃) serving as the second-element-containing gas will be described.

### Substrate Loading and Placing Process (S102)

In the substrate processing apparatus 100, when the susceptor 212 is lowered to a transfer position of the wafer 200, the lift pins 207 pass through the through holes 214 of the susceptor 212. As a result, the lift pins 207 protrude from the surface of the susceptor 212 by a predetermined height. Next, the gate valve 205 is opened and enables the transfer space 203 to communicate with the transfer chamber (not illustrated). Then, the wafer 200 is loaded from the transfer chamber into the transfer space 203 using the wafer transfer device (not illustrated) and transferred to the lift pins 207. Accordingly, the wafer 200 is supported in a horizontal orientation on the lift pins 207 protruding from the surface of the susceptor 212.

When the wafer 200 is loaded in the process container 202, the wafer transfer device is evacuated to the outside of the process container 202, the gate valve 205 is closed, and an inside of the process container 202 is sealed. Then, when the susceptor 212 is lifted, the wafer 200 is placed on the substrate support surface 211 installed in the susceptor 212 and the wafer 200 is lifted to the processing position in the above-described reaction zone 201.

Also, when the wafer 200 is placed on the susceptor 212, the surface of the wafer 200 is controlled to have a predetermined temperature by supplying power to the heater 213 embedded in the susceptor 212. The temperature of the wafer 200 is, for example, room temperature or more and 500° C. or less, and preferably, room temperature or more and 400° C. or less. In this case, a temperature of the heater 213 is adjusted by controlling power supply to the heater 213 based on information on a temperature detected by a temperature sensor (not illustrated). The heater 213 is continuously controlled until the substrate loading and placing process (S102) to a substrate unloading process (S106) to be described below are completed.

### Film Forming Process (S104)

Next, a film forming process (S104) is performed. Hereinafter, the film forming process (S104) will be described in detail with reference to FIG. 4. Also, the film forming process (S104) is a cyclic process of repeating a process of alternately supplying other processing gases.

### First Processing Gas Supply Process (S202)

When the wafer 200 is heated to a desired temperature, the valve 243d is opened and the MFC 243c is adjusted such that the flow rate of TiCl₄ gas is a predetermined flow rate. Also, the TiCl₄ gas has a supply flow rate of, for example, 100 sccm or more and 5,000 sccm or less. In this case, the valve 224 is open and the pressure of the reaction zone 201 is controlled by the APC 223 to a predetermined pressure. Also, the valve 245d of the third gas supply system is opened and N₂ gas is supplied through the third gas supply pipe 245a. Also, the N₂ gas may flow through the first inert gas supply system. Also, before this process, supply of the N₂ gas through the third gas supply pipe 245a may start.

The TiCl₄ gas supplied to the process container 202 is supplied to the wafer 200. In the surface of the wafer 200, when the TiCl₄ gas is in contact with the wafer 200, a titanium-containing layer serving as “a first-element-containing layer” is formed.

The titanium-containing layer is formed, for example, to have a predetermined thickness and a predetermined distribution according to the pressure in the reaction zone 201, the flow rate of the TiCl₄ gas, the temperature of the susceptor 212 and the like. Also, a predetermined film may be formed on the wafer 200 in advance. Also, a predetermined pattern may be formed on the wafer 200 or the predetermined film in advance.

Once a predetermined time has elapsed after the supply of the TiCl₄ gas is started, the valve 243d is closed to stop the supply of the TiCl₄ gas.

### Purge Process (S204)

Next, a purge process in the reaction zone 201 is performed by supplying the N₂ gas through the third gas supply pipe 245a. In this case, the valve 224 is open and the pressure of the reaction zone 201 is controlled by the APC 223 to a predetermined pressure. Accordingly, in the first processing gas supply process (S202), the TiCl₄ gas which is not bonded to the wafer 200 is removed from the reaction zone 201 through the exhaust pipe 222.

When the purge process in the reaction zone 201 is completed, the valve 224 is opened to restart control of the pressure by the APC 223.

### Second Processing Gas Supply Process (S206)

After the purge process (S204), the valve 244d is opened to start the supply of the nitrogen-containing gas in a plasma state to the reaction zone 201. In the present embodiment, as the nitrogen-containing gas, ammonia (NH₃) is used.

In this case, the MFC 244c is adjusted such that a flow rate of a nitrogen-containing gas is a predetermined flow rate. Also, the nitrogen-containing gas has the supply flow rate of, for example, 100 sccm or more and 5,000 sccm or less. Also, N₂ gas serving as a carrier gas may flow with the nitrogen-containing gas through the second inert gas supply system. Also, in this process, the valve 245d of the third gas supply system is opened and the N₂ gas is supplied through the third gas supply pipe 245a. The N₂ gas supplied through the third gas supply pipe 245a is formed in a spiral-shaped flow in the internal space 241g, which is an outer surface of the tube 261 around the tube 261 and formed in an inner surface of the upper portion 241 and the gas distribution channel 231b.

The nitrogen-containing gas in a plasma state, which is discharged through a front end 261a of the tube, is supplied to a center 200a of the wafer. Also, the nitrogen-containing gas is placed on an eddy of the inert gas formed in the vicinity of the front end 261a of the tube and is transferred to the outer circumference 200b of the wafer 200.

The nitrogen-containing gas is supplied to the center 200a of the wafer and the outer circumference 200b of the wafer. When the pre-formed titanium-containing layer is modified by the nitrogen-containing gas, a layer containing, for example, the element titanium and the element nitrogen is formed on the wafer 200. Therefore, it is possible to uniformly form a film in a plane of the wafer.

The modified layer is formed, for example, to have a predetermined thickness, a predetermined distribution and a predetermined penetration depth of an oxygen component and the like with respect to the titanium-containing layer according to the pressure in the reaction zone 201, the flow rate of the nitrogen gas, the temperature of the susceptor 212 and the like.

After a predetermined time has elapsed, the valve 244d is closed to stop the supply of the nitrogen-containing gas.

Also, in the process S206, in the same manner as the above-described process S202, the valve 224 is opened and the pressure in the reaction zone 201 is controlled by the APC 223 to a predetermined pressure.

### Purge Process (S208)

Next, in the same manner as the process S204, a purge process is performed. Since operations of respective units are the same as those described in the process S204, description thereof is omitted.

### Determination (S210)

The controller 280 determines whether or not the one cycle has been performed a predetermined number of times (n cycles).

When the one cycle has not been performed the predetermined number of times [NO in S210], the cycle including the first processing gas supply process (S202), the purge process (S204), the second processing gas supply process (S206) and the purge process (S208) is repeated. When the one cycle has been performed the predetermined number of times [YES in S210], the process illustrated in FIG. 4 ends.

Next, returning to FIG. 3, the substrate unloading process (S106) is performed.

### Substrate Unloading Process (S106)

In the substrate unloading process (S106), the susceptor 212 is lowered and the wafer 200 is supported on the lift pins 207 protruding from the surface of the susceptor 212. Accordingly, the wafer 200 moves from the processing position to the transfer position. Then, the gate valve 205 is opened and the wafer 200 is unloaded from the process container 202 using the wafer transfer device. In this case, the valve 245d is closed and the supply of the inert gas into the process container 202 through the third gas supply system is stopped.

### Process of Determining Number of Times of Processing has Been Performed (S108)

After the wafer 200 is unloaded, it is determined whether or not the thin film forming process has been performed the predetermined number of times. When it is determined that the thin film forming process has been performed the predetermined number of times, the process ends.

### Second Embodiment

Next, a second embodiment will be described with reference to FIG. 9. FIG. 9 is an enlarged view illustrating the front end 261a of the tube 261.

First, a comparative example will be described with reference to FIG. 12. Arrows 301 represent the flow of the gas (the first-element-containing gas) outside the tubes 261 and arrows 302 represent the flow of the gas (the second-element-containing gas) supplied through the inner surfaces of the tubes 261.

Since front ends 303 have angular shapes, the first-element-containing gas supplied in the first processing gas supply process (S202) collides with the front ends 303 of the outer surface of the tube constituting the tube 261. Also, the first-element-containing gas is attached thereto. Also, since the front ends 303 of the tubes 261 have angular shapes, the gas that flows back into front ends 304 of the inner surfaces of the tubes 261 collides with the front ends 304 and is attached thereto.

Thus, in the second gas supply process (S206), when the second-element-containing gas is supplied, the second-element-containing gas is in contact with the first-element-containing gas attached to the front ends 303 and 304 to react and an unintended film is formed on the front ends 303 and 304. Since the formed film has uncontrolled film density and intensity, the formed film peels off during the substrate processing and thus it is considered to have an adverse effect on film quality.

The present embodiment addresses this problem. This will be described in detail next with reference to FIG. 9. In FIG. 9, the front ends of the outer surfaces of the tubes 261 and the front ends of the inner surfaces thereof have round shapes. In such a configuration, since the flow of the gas is not inhibited, it is possible to suppress the forming of the unintended film.

### Third Embodiment

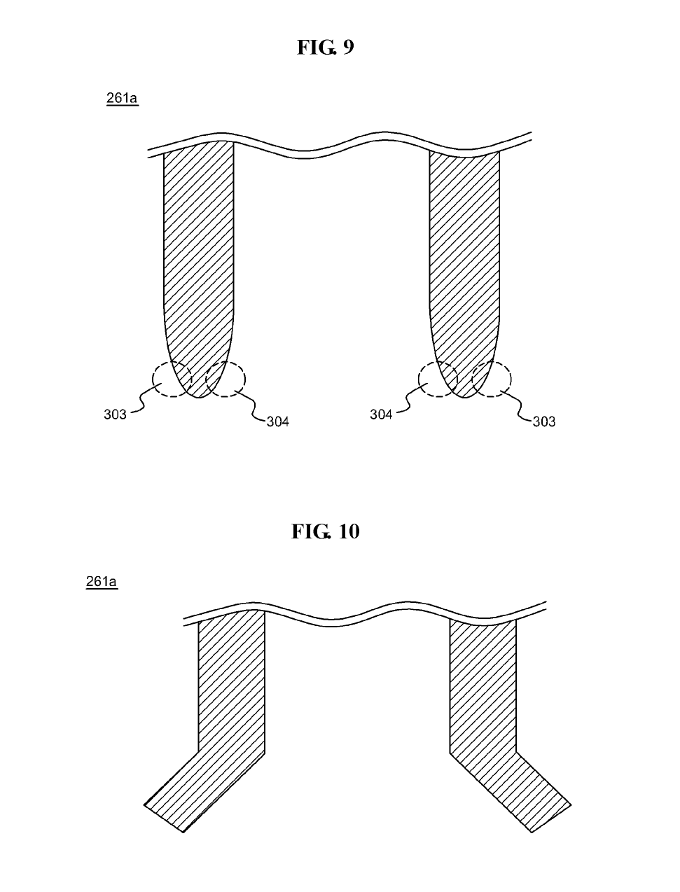

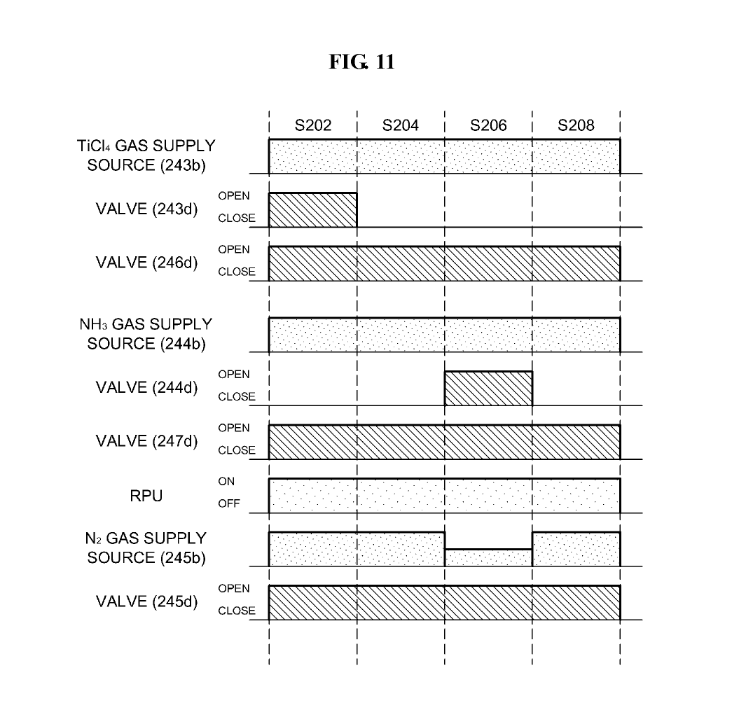

Next, a third embodiment will be described with reference to FIG. 10. In the present embodiment, the size of the front end of the tube 261 is configured to increase toward the reaction zone 201. In such a configuration, since the second-element-containing gas flows along the front end, it is easy to join the second-element-containing gas to an eddy which flows along the outer circumference (outer surface) of the tube 261.

### Fourth Embodiment

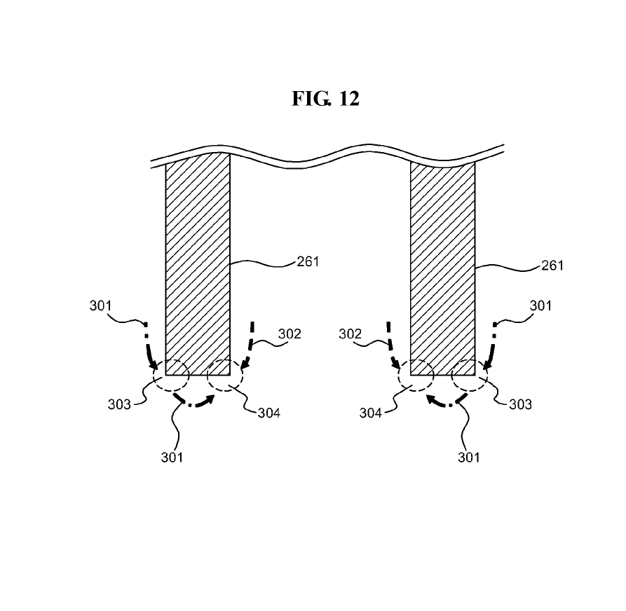

Next, a fourth embodiment will be described with reference to FIG. 11. FIG. 11 is a view illustrating a modification of the gas flow (illustrated in FIG. 5) of the first embodiment. In the second processing gas supply process (S206), a supply amount of the inert gas is changed. Specifically, the supply amount of the inert gas is smaller than that in the first processing gas supply process (S202). In such a configuration, the probability of the first processing gas activated by being exposed to the plasma colliding with the inert gas is reduced, and as a result, the deactivation of the plasma may be further suppressed.

While the film forming technique has been described above in various exemplary embodiments of the present invention, the invention is not limited thereto. For example, the present invention may be applied to a film forming process other than the process for forming the thin film illustrated above or may be applied to other substrate processes such as diffusion, oxidation and nitriding processes. Also, the present invention may be applied to other substrate processing apparatuses such as a film forming apparatus, an etching apparatus, an oxidation apparatus, a nitriding apparatus, a coating apparatus and a heating apparatus. Also, it is possible to replace a part of the configuration of an embodiment with the configuration of another embodiment and it is also possible to add the configuration of another embodiment to the configuration of an embodiment. Also, it is also possible to add, remove and replace the configuration of another embodiment to, from and with a part of the configuration of each embodiment.

According to the present invention, a technique of forming a uniform film in a plane of a substrate can be provided.

### Preferred Embodiments of the Present Invention

Hereinafter, preferred embodiments according to the present invention are supplementarily noted.

### Supplementary Note 1

According to an aspect of the present invention, there is provided a substrate processing apparatus including: a substrate support where a substrate is placed; a cover facing at least a portion of the substrate support, the cover including a gas supply channel at a center thereof; a gas supply structure connected to the gas supply channel; a reactive gas supply unit connected to the gas supply structure and including a plasma generating unit; a tube connected to the reactive gas supply unit and extending from the gas supply structure to the gas supply channel; and a gas supply unit connected to the gas supply structure and configured to supply a gas to a space between an outer surface of the tube and an inner surface of the gas supply structure.

### Supplementary Note 2

In the substrate processing apparatus of Supplementary note 1, preferably, the gas supply channel is tapered such that a diameter of the gas supply channel increases when closer to the substrate support, and a front end of the tube is disposed in the gas supply channel.

### Supplementary Note 3

In the substrate processing apparatus of Supplementary note 2, preferably, the gas supply structure includes a cylinder, the reactive gas supply unit is connected to one end of the cylinder, and the gas supply unit includes a gas supply pipe connected to a side of the cylinder.

### Supplementary Note 4

In the substrate processing apparatus of Supplementary note 3, preferably, the gas supply structure further includes an eddy generating unit installed in the cylinder and configured to generate an eddy, and the gas supply pipe is connected to the eddy generating unit.

### Supplementary Note 5

In the substrate processing apparatus of any one of Supplementary notes 1 through 4, preferably, the substrate processing apparatus further includes a source gas supply unit connected to the gas supply structure and configured to supply a source gas.

### Supplementary Note 6

In the substrate processing apparatus of any one of Supplementary notes 1 through 5, preferably, the gas supply unit is configured to supply an inert gas through the gas supply pipe, and a connecting hole connecting the gas supply pipe to the gas supply structure is disposed higher than a connecting hole connecting a supply pipe of the source gas supply unit to the gas supply structure.

### Supplementary Note 7

In the substrate processing apparatus of Supplementary note 6, preferably, the source gas supply unit, the gas supply unit and the reactive has supply unit are configured to: open valves of the source gas supply unit and the gas supply unit and close a valve of the reactive has supply unit when the source gas is supplied to the gas supply channel; and close the valve of the source gas supply unit and close the valves of the gas supply unit and the reactive has supply unit when the reactive gas is supplied to the gas supply channel.

### Supplementary Note 8

In the substrate processing apparatus of Supplementary note 7, preferably, the source gas and the reactive gas are supplied alternately.

### Supplementary Note 9

According to another aspect of the present invention, there is provided a method of manufacturing a semiconductor device including: (a) placing a substrate on a substrate support; and (b) supplying a reactive gas in plasma state through a reactive gas supply tube inserted in a gas supply channel disposed at a center of a cover facing at least a portion of the substrate support, and supplying an inert gas to a space between an outer surface of the reactive gas supply tube and an inner surface of a gas supply structure.

### Supplementary Note 10

According to still another aspect of the present invention, there is provided a program for causing a computer to control a substrate processing apparatus to perform: (a) placing a substrate on a substrate support; and (b) supplying a reactive gas in plasma state through a reactive gas supply tube inserted in a gas supply channel disposed at a center of a cover facing at least a portion of the substrate support, and supplying an inert gas to a space between an outer surface of the reactive gas supply tube and an inner surface of a gas supply structure.

### Supplementary Note 11

According to still another aspect of the present invention, there is provided a non-transitory computer-readable recording medium storing a program for causing a computer to control a substrate processing apparatus to perform: (a) placing a substrate on a substrate support; and (b) supplying a reactive gas in plasma state through a reactive gas supply tube inserted in a gas supply channel disposed at a center of a cover facing at least a portion of the substrate support, and supplying an inert gas to a space between an outer surface of the reactive gas supply tube and an inner surface of a gas supply structure.

What is claimed is:

1. A substrate processing apparatus comprising:
a substrate support where a substrate is placed;
a cover facing at least a portion of the substrate support, the cover comprising a gas supply channel at a center thereof;
a gas supply structure connected to the gas supply channel;
a reactive gas supply unit connected to the gas supply structure and comprising a plasma generating unit;
a tube connected to the reactive gas supply unit and extending from the gas supply structure to the gas supply channel; and
a gas supply unit connected to the gas supply structure and configured to supply a gas to a space between an outer surface of the tube and an inner surface of the gas supply structure.

2. The substrate processing apparatus of claim 1, wherein the gas supply channel is tapered such that a diameter of the gas supply channel increases when closer to the substrate support, and a front end of the tube is disposed in the gas supply channel.

3. The substrate processing apparatus of claim 2, wherein the gas supply structure comprises a cylinder, the reactive gas supply unit is connected to one end of the cylinder, and the gas supply unit comprises a gas supply pipe connected to a side of the cylinder.

4. The substrate processing apparatus of claim 3, wherein the gas supply structure further comprises an eddy generating unit installed in the cylinder and configured to generate an eddy, and the gas supply pipe is connected to the eddy generating unit.

5. The substrate processing apparatus of claim 4, further comprising a source gas supply unit connected to the gas supply structure and configured to supply a source gas.

6. The substrate processing apparatus of claim 5, wherein the gas supply unit is configured to supply an inert gas through the gas supply pipe, and a connecting hole connecting the gas supply pipe to the gas supply structure is disposed higher than a connecting hole connecting a supply pipe of the source gas supply unit to the gas supply structure.

7. The substrate processing apparatus of claim 3, further comprising a source gas supply unit connected to the gas supply structure and configured to supply a source gas.

8. The substrate processing apparatus of claim 7, wherein the gas supply unit is configured to supply an inert gas through the gas supply pipe, and a connecting hole connecting the gas supply pipe to the gas supply structure is disposed higher than a connecting hole connecting a supply pipe of the source gas supply unit to the gas supply structure.

9. The substrate processing apparatus of claim 2, further comprising a source gas supply unit connected to the gas supply structure and configured to supply a source gas.

10. The substrate processing apparatus of claim 9, wherein the gas supply unit is configured to supply an inert gas through the gas supply pipe, and a connecting hole connecting the gas supply pipe to the gas supply structure is disposed higher than a connecting hole connecting a supply pipe of the source gas supply unit to the gas supply structure.

11. The substrate processing apparatus of claim 1, wherein the gas supply structure comprises a cylinder, the reactive gas supply unit is connected to one end of the cylinder, and the gas supply unit comprises a gas supply pipe connected to a side of the cylinder.

12. The substrate processing apparatus of claim 11, wherein the gas supply structure further comprises an eddy generating unit installed in the cylinder and configured to generate an eddy, and the gas supply pipe is connected to the eddy generating unit.

13. The substrate processing apparatus of claim 12, further comprising a source gas supply unit connected to the gas supply structure and configured to supply a source gas.

14. The substrate processing apparatus of claim 13, wherein the gas supply unit is configured to supply an inert gas through the gas supply pipe, and a connecting hole connecting the gas supply pipe to the gas supply structure is disposed higher than a connecting hole connecting a supply pipe of the source gas supply unit to the gas supply structure.

15. The substrate processing apparatus of claim 11, further comprising a source gas supply unit connected to the gas supply structure and configured to supply a source gas.

16. The substrate processing apparatus of claim 15, wherein the gas supply unit is configured to supply an inert gas through the gas supply pipe, and a connecting hole connecting the gas supply pipe to the gas supply structure is disposed higher than a connecting hole connecting a supply pipe of the source gas supply unit to the gas supply structure.

17. The substrate processing apparatus of claim 1, further comprising a source gas supply unit connected to the gas supply structure and configured to supply a source gas.

18. The substrate processing apparatus of claim 17, wherein the gas supply unit is configured to supply an inert gas through the gas supply pipe, and a connecting hole connecting the gas supply pipe to the gas supply structure is disposed higher than a connecting hole connecting a supply pipe of the source gas supply unit to the gas supply structure.

19. The substrate processing apparatus of claim 18, wherein the source gas supply unit, the gas supply unit and the reactive has supply unit are configured to: open valves of the source gas supply unit and the gas supply unit and close a valve of the reactive has supply unit when the source gas is supplied to the gas supply channel; and close the valve of the source gas supply unit and close the valves of the gas supply unit and the reactive has supply unit when the reactive gas is supplied to the gas supply channel.
